(19) United States
(12) Patent Application Publication
(10) Pub. No.: US 2024/0355738 A1
(43) Pub. Date: Oct. 24, 2024

(54) Power Semiconductor Devices Including Beryllium Metallization

(71) Applicant: Wolfspeed, Inc., Durham, NC (US)

(72) Inventors: Afshin Dadvand, Durham, NC (US); Devarajan Balaraman, Apex, NC (US)

(21) Appl. No.: 18/304,869

(22) Filed: Apr. 21, 2023

(51) Int. Cl. H01L 23/532; H01L 23/00; H01L 23/29; H01L 29/45

(52) U.S. Cl. CPC H01L 23/53219; H01L 23/291; H01L 23/293; H01L 23/53233; H01L 24/05; H01L 24/08; H01L 24/48; H01L 29/452; H01L 2224/05147; H01L 2224/05624; H01L 2224/08113; H01L 2224/48245; H01L 2924/01004; H01L 2924/12032; H01L 2924/13064; H01L 2924/13091

(57) ABSTRACT

Semiconductor devices and methods are provided. In one example, a semiconductor device includes an active region comprising one or more active semiconductor cells. The semiconductor device includes a metallization structure on the active region. The metallization structure includes beryllium.

### FIELD

The present disclosure relates generally to power semiconductor devices.

### BACKGROUND

A wide variety of power semiconductor devices are known in the art including, for example, power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials such as silicon carbide or gallium nitride-based materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes an active region comprising one or more active semiconductor cells. The semiconductor device includes a metallization structure on the active region. The metallization structure comprises beryllium.

Another example aspect of the present disclosure is directed to a semiconductor device. The semiconductor device includes an active region comprising one or more silicon carbide-based MOSFETs. The semiconductor device includes a metallization structure on the active region. The metallization structure includes a bonding pad associated with a gate contact, a source contact, or a drain contact for the semiconductor device. The metallization structure comprises beryllium.

Another example aspect of the present disclosure is directed to a method. The method includes depositing a metallization structure on an active region comprising one or more wide band gap semiconductor cells. The metallization structure comprises beryllium.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a perspective view of a semiconductor device including a metallization structure according to example embodiments of the present disclosure;

FIG. 2 depicts a cross-sectional view of an example semiconductor device including a metallization structure according to example embodiments of the present disclosure;

FIG. 3 depicts example metallization structures of a semiconductor device according to example embodiments of the present disclosure;

FIG. 4 depicts example metallization structures of a semiconductor device according to example embodiments of the present disclosure;

FIG. 5 depicts a cross-sectional view of the semiconductor device of FIG. 4;

FIG. 6 depicts an example semiconductor package of a semiconductor device according to example embodiments of the present disclosure;

FIG. 7 depicts an example semiconductor package of a semiconductor device according to example embodiments of the present disclosure; and

FIG. 8 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to semiconductor devices, and more particularly to semiconductor devices having a metallization structure that includes beryllium, such as a beryllium alloy. As used herein, the term “alloy” refers to a mixture of metal elements.

A “metallization structure” is any layer, structure, or other portion of a semiconductor device, semiconductor die, or semiconductor package, that incorporates a metal for thermal and/or electrical conduction. A “metallization structure” may include, for instance, a contact, an interconnect, a bonding pad, backside metallization, metal layer, or metal coating.

A semiconductor device may include, for instance, a semiconductor die. The semiconductor die may include one or more active regions of semiconductor and one or more metallization structures. The active region may include one or more active semiconductor cells with individual “unit cell” semiconductor devices, such as MOSFETs, Schottky diodes, high electron mobility transistor devices (HEMTs). The semiconductor die may be provided in a semiconductor package. The semiconductor package may include, for instance, a housing (e.g., epoxy mold compound (EMC)), a submount such as a lead frame, and connection structures between the semiconductor die and the submount (e.g., die attach material and/or wire bonds). In some examples, a passivation layer may be provided on the semiconductor die (e.g., a silicon nitride and/or polyimide passivation layer).

The semiconductor die may be based on a wide band gap semiconductor material. A wide band gap semiconductor material has a band gap greater than about 1.40 eV, such as silicon carbide and/or a Group III-nitride (e.g., gallium nitride). For instance, in some examples, the active semiconductor cells may include one or more silicon carbide-based MOSFETs. In some examples, the active semiconductor cells may include one or more silicon carbide-based Schottky diodes. In some examples, the active semiconductor cells may include one or more Group III-nitride based transistor devices, such as gallium nitride-based high electron mobility transistor devices. The active semiconductor cells may include other devices without deviating from the scope of the present disclosure, such as other wide band gap semiconductor devices.

A metallization structure in a semiconductor device may be used, for instance, to provide an electrically conductive and/or thermally conductive connection to the active region of the semiconductor device. The metallization structure may include, for instance, one or more contacts, interconnections, bonding pads, backside layers, metal layers, or metal coatings of the semiconductor device.

Power semiconductor devices may experience anomalies and/or failures resulting from the deformation, delamination, shifting, moving (e.g., glacial moving) of copper and/or aluminum metallization structures. In addition, cracks in a passivation layer of the power semiconductor device may result from thermomechanical stress to a semiconductor die surface during different reliability tests, such as thermal cycling (TC). A coefficient of thermal expansion (CTE) mismatch between the EMC and different parts of a semiconductor die as well as the high temperature flexural modulus of EMC may induce a shear stress from the edges to the center of the semiconductor die, leading to deformation, delamination, and/or ratcheting of metallization structures. This may consequently provide stress on the passivation layer and may ultimately induce defects or cracks in the passivation layer.

In some power semiconductor device packages, an aluminum-copper alloy has been introduced as an alternative metallization material for metallization structures relative to aluminum. The aluminum-copper alloy may exhibit slightly higher resistance to metal deformation as well as higher resistance to metal corrosion in the presence of ionic impurities. However, metallization structures based on an aluminum-copper alloy may suffer from residual stress, thermal stress relaxation, and accelerated galvanic corrosion of aluminum, particularly at an interface with a connection structure such as a wire bond. Moreover, the CTE mismatch between the metallization structure and other parts of semiconductor die, including a silicon nitride passivation layer or other passivation layer is still of concern.

Aluminum-copper alloy is also vulnerable to damage in high power wire-bonding processes where a thick aluminum wire (e.g., 15 mil or 20 mil) or copper wire is used to achieve higher ampacity. This may induce further damage to the semiconductor die. The damage may be even more pronounced with bonding pads having a smaller thickness (e.g., about 4 μm). Increased metallization pad thickness (e.g., about 5 μm to about 6 μm), on the other hand, may have adverse effects such as risk of metal migration. Moreover, the diffusion of copper to the semiconductor die when an aluminum copper alloy is used for metallization structure may cause reliability concerns.

According to example aspects of the present disclosure, a semiconductor device may include a metallization structure. The metallization structure may include beryllium. For instance, in some embodiments, the metallization structure may include a beryllium alloy. The metallization structure may include copper and beryllium (e.g., a copper-beryllium alloy). The metallization structure may include aluminum and beryllium (e.g., an aluminum-beryllium alloy).

In some examples, the metallization structure may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, the metallization structure may be an electrode/contact (e.g., source, drain, and/or gate contact). In some examples, the metallization structure may be an interconnect. In some examples, the metallization structure may be a bonding pad (e.g., for wire bonding). In some examples, the metallization structure may provide backside metallization or other metallization layer.

In some examples, the mechanical and/or electrical properties of the metallization structure can be controlled and/or tuned by the ratio of beryllium to the other metals in the metallization structure. For instance, the metallization layer may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

Beryllium is a low-density metal which possesses a high thermal and electrical conductivity, high strength, high resistance to fatigue and corrosion, and low response to magnetic fields. Beryllium may also act as a CTE moderator. Beryllium alloys, such as copper-beryllium alloys, aluminum-beryllium alloys, and ternary beryllium alloys, may possess highly stable tensile properties even at high temperatures (e.g., in a range of about 250° C. to about 300° C.). The mechanical stability of these alloy may remain intact over a wide range of temperatures, exhibiting inherent resistance to thermal stress relaxation at high temperatures and during different reliability tests such as TC, High Temperature Reverse Bias (HTRB) testing, High Voltage-High Humidity High Temperature Reverse Bias (HV-H3TRB) testing, etc. This may reduce the deformation, delamination, and/or ratcheting phenomena of metallization structures and may consequently reduce damage to the passivation layer. In addition, the corrosion resistance of beryllium metal alloys is expected to exceed the corrosion resistance of aluminum and copper.

Aspects of the present disclosure provide technical effects and benefits. For example, metallization structures that include beryllium according to examples of the present disclosure may address different reliability challenges in high performance semiconductor packaging, such as aluminum splash out, pad cratering, galvanic corrosion, passivation layer cracks and the shift or deformation of metallization structures. A metallization structure including beryllium (e.g., beryllium alloy) may exhibit similar CTE values to that of different parts of the semiconductor die while being resistant to the mechanical stress posed by, for instance, the encapsulating material (EMC) of the semiconductor package. Moreover, due to improved structural robustness of the metallization structure including beryllium, these alloys can increase the reliability of wire bonding processes and may allow for the reduction in thickness of the metallization structure (e.g., thickness of the bonding pads) without risk of damaging underlying layers in the semiconductor die during a wire bonding process.

In some examples, using a metallization structure having beryllium (e.g., beryllium alloy) instead of aluminum or aluminum-copper alloy can reduce failures during testing of the semiconductor device. In addition, the metallization structure may reduce delamination of the metallization structure. In some examples, using a metallization structure having beryllium (e.g., beryllium alloy) instead of aluminum or aluminum-copper alloy can allow for thicker (e.g., 15 mil or 20 mil) wire bonding integration (Al or Cu wire bond) in semiconductor packages. In some examples, using a metallization structure having beryllium (e.g., beryllium alloy) instead of aluminum or aluminum-copper alloy can enhance the ability of the metallization structure to withstand the stress from the EMC without passivation layer cracking. In some examples, using a metallization structure having beryllium (e.g., beryllium alloy) instead of aluminum or aluminum-copper alloy can reduce the diffusion of copper to the semiconductor die.

In addition, aluminum metallization is usually deposited at a temperature in a range of about 400° C. to about 450° C. for better film uniformity. However, high temperatures of about 400° C. or greater may force the grain to recrystallize and grow at larger size consequently lowering its mechanical strength. The addition of beryllium may increase the recrystallization temperature by about 100° C. or more, leading to increased mechanical stability.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures. Those of ordinary skill in the art, using the disclosures provided herein, will understand that the power semiconductor devices according to example embodiments of the present disclosure may be used with any semiconductor material, such as other wide band gap semiconductor materials. without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

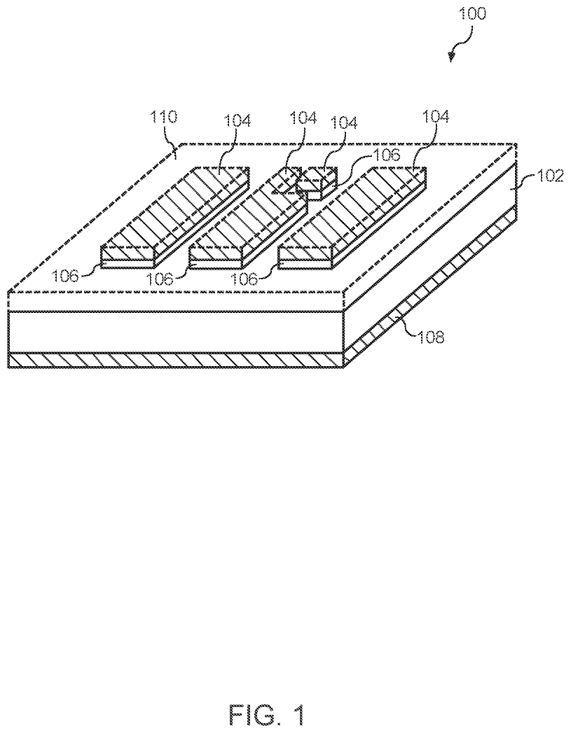

FIG. 1 depicts an example semiconductor device 100 according to example embodiments of the present disclosure. The semiconductor device 100 may be, for instance, a semiconductor die. The semiconductor device 100 may include a semiconductor structure 102 with active regions including one or more active semiconductor cells (e.g., silicon carbide-based MOSFETs, silicon carbide-based Schottky diodes, Group III-nitride based HEMTs, etc.). The semiconductor structure 102 may include a wide band gap semiconductor, such as silicon carbide and/or a Group III-nitride (e.g., GaN, AlGaN, etc.). The semiconductor structure 102 may include one or more epitaxial layers formed on a substrate, such as a silicon carbide substrate.

The semiconductor device 100 may include one or more metallization structures. The one or more metallization structures may include, for instance, bonding pads 104. Bonding pads 104 may be used to make an electrical connection to the semiconductor device 100 using connection structures, such as wire bonds. The bonding pads 104 may be disposed on an adhesion layer 106 to secure the bonding pads 104 to the semiconductor structure 102 to provide, for instance, a gate connection, source connection, kelvin connection, sensor connection, or other suitable connection. The adhesion layer 106 may be, for instance, titanium. The bonding pads 104 may have a thickness of about 4 μm or less in some embodiments.

In some examples, the semiconductor device 100 may include a backside metallization structure 108 on the semiconductor structure 102. In some semiconductor packages, the backside metallization structure 108 may be secured to a submount (e.g., a lead frame of a semiconductor package) using, for instance, a die-attach material to provide a thermal and/or electrical connection for the semiconductor device 100 (e.g., a drain connection).

The semiconductor device 100 may include a passivation layer 110. The bonding pads 104 may be exposed through openings in the passivation layer 110. The passivation layer may include one or more suitable passivation materials, such as silicon nitride. In some examples, the passivation layer 110 may be a polymer, such as polyimide. In some examples, the passivation layer 110 may be SiO₂, MgOx, MgNx, ZnO, SiNx, SiOx or other dielectric material.

According to example embodiments of the present disclosure, the bonding pads 104 and/or the backside metallization structure 108 may include beryllium. For instance, the bonding pads 104 and/or the backside metallization structure 108 may include beryllium. For instance, in some embodiments, the bonding pads 104 and/or the backside metallization structure 108 may include a beryllium alloy. The bonding pads 104 and/or the backside metallization structure 108 may include copper and beryllium (e.g., a copper-beryllium alloy). The bonding pads 104 and/or the backside metallization structure 108 may include aluminum and beryllium (e.g., an aluminum-beryllium alloy).

In some examples, the bonding pads 104 and/or the backside metallization structure 108 may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, the bonding pads 104 and/or the backside metallization structure 108 may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

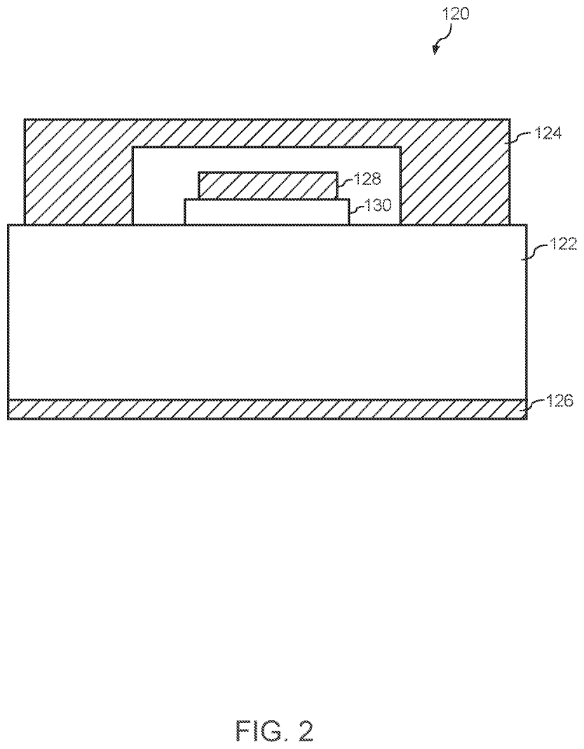

FIG. 2 depicts a cross-sectional view of at least a portion of a semiconductor device 120 according to example embodiments of the present disclosure. The semiconductor device 120 shown in FIG. 2, in some embodiments, may be a single unit cell of an active semiconductor cell of the semiconductor device 100 of FIG. 1.

As shown, the semiconductor device 120 includes a semiconductor structure 122. The semiconductor structure 122 may include one or more wide band gap semiconductor materials and may include doping and/or different epitaxial layer structures to form one or more active semiconductor cells for semiconductor devices (e.g., silicon carbide-based MOSFETs, silicon carbide-based Schottky diodes, Group III-nitride based HEMTs, etc.). The semiconductor structure 122 may include one or more epitaxial layers formed on a substrate, such as a silicon carbide substrate.

The semiconductor device 120 may include metallization structures, such as contacts for the semiconductor device 120. In the example of FIG. 2, the one or more metallization structures may include a source contact 124, a drain contact 126, and/or a gate contact 128. A gate dielectric layer 130 (e.g., silicon dioxide) may be disposed between the gate contact 128 and the semiconductor structure 122. The semiconductor device 120 may include one or more passivation layers (e.g., silicon nitride layers, polyimide layers, etc.) not illustrated in FIG. 2 for simplicity of illustration.

According to example embodiments of the present disclosure, at least a portion of one or more of the metallization structures of FIG. 2, including at least a portion of one or more of the source contact 124, drain contact 126 and/or the gate contact 128, may include beryllium. For instance, in some embodiments, at least a portion of the source contact 124, drain contact 126 and/or the gate contact 128 may include a beryllium alloy. At least a portion of the source contact 124, drain contact 126 and/or the gate contact 128 may include copper and beryllium (e.g., a copper-beryllium alloy). At least a portion of the source contact 124, drain contact 126 and/or the gate contact 128 may include aluminum and beryllium (e.g., an aluminum-beryllium alloy).

In some examples, at least a portion of the source contact 124, drain contact 126 and/or the gate contact 128 may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, at least a portion of the source contact 124, drain contact 126 and/or the gate contact 128 may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

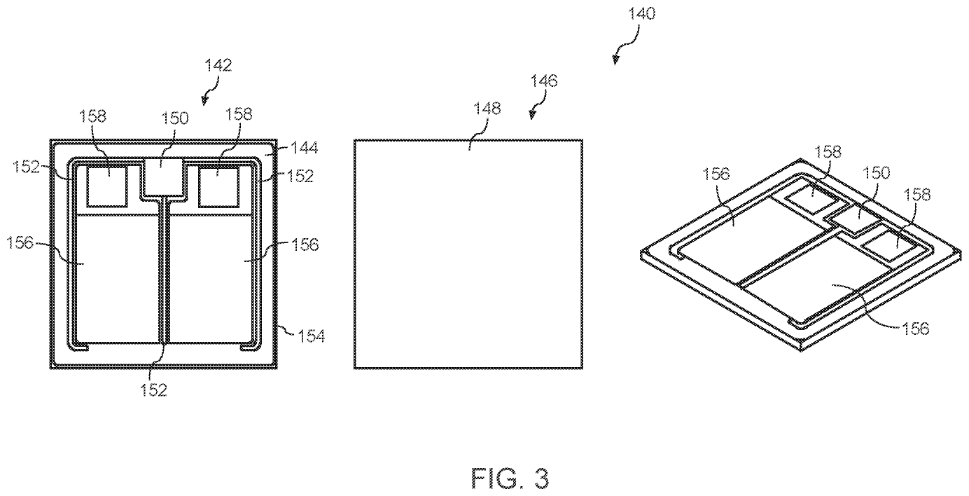

FIG. 3 depicts example metallization layers of a semiconductor device 140 that includes a topside metallization layer 142 on a semiconductor structure 144. The semiconductor device 140 may also include a backside metallization layer 146. The backside metallization layer 146 may include a drain attach pad 148 on the backside of the semiconductor structure 144. The semiconductor structure 144 may include one or more wide band gap semiconductor materials and may include doping and/or different epitaxial layer structures to form one or more active semiconductor cells for semiconductor devices (e.g., silicon carbide-based MOSFETs, silicon carbide-based Schottky diodes, Group III-nitride based HEMTs, etc.). The semiconductor structure 144 may include one or more epitaxial layers formed on a substrate, such as a silicon carbide substrate.

The topside metallization layer 142 may include metallization structures including a gate pad 150, gate runners 152, an edge termination structure 154, source pads 156, and/or additional bond pads 158 (e.g., source kelvin bond pads or sensor bond pads). The plurality of gate runners 152 (e.g., gate buses) may extend from the gate pad 150 to better distribute a gate signal to the outer edges and to the middle of the power semiconductor device 140. The edge termination structure 154 may be around the perimeter of the power semiconductor device 140 to buffer an electric field so that voltage over distance is reduced.

The metallization layer 142 may include metallized pads (e.g., the gate pad 150 and source pads 156) for power and signal connection to other components (e.g., submounts, lead frames, terminals, etc.) so that the metallization layer 142 acts as a bonding layer for the power semiconductor device 140. The gate pad 150 and/or the source pads 156 may have a thickness of 4 μm or less. Signal connections to the gate pad 150 may be implemented, for instance, using wire bond(s). The source pads 156 may be directly on the active region of the semiconductor structure 144. A power connection may be made to the source pads 156 using a clip or similar attach which is directly soldered, sintered, welded to the source pads 156. The source pads 156 may serve as source contact(s) or other contacts (e.g., ohmic contacts, Schottky contacts, etc.) for the semiconductor cells in the active region(s) of the semiconductor structure 144 of the power semiconductor device 140.

The power semiconductor device 140 may include additional bonding pads 156 (e.g., for connection to wire bonds or other connection structure). The additional bonding pads 156 may be used, for instance, for source kelvin connection(s) and/or sensor connections for the semiconductor device 140.

According to example embodiments of the present disclosure, at least a portion of one or more of the metallization structures of FIG. 3, including at least a portion of one or more of the gate pad 150, gate runners 152, edge termination structure 154, source pads 156, additional bond pads 158, and/or the drain attach pad 148, may include beryllium. For instance, in some embodiments, at least a portion of one or more of the gate pad 150, gate runners 152, edge termination structure 154, source pads 156, additional bond pads 158, and/or the drain attach pad 148 may include a beryllium alloy. At least a portion of one or more of the gate pad 150, gate runners 152, edge termination structure 154, source pads 156, additional bond pads 158, and/or the drain attach pad 148 may include copper and beryllium (e.g., a copper-beryllium alloy). At least a portion of one or more of the gate pad 150, gate runners 152, edge termination structure 154, source pads 156, additional bond pads 158, and/or the drain attach pad 148 may include aluminum and beryllium (e.g., an aluminum-beryllium alloy).

In some examples, at least a portion of one or more of the gate pad 150, gate runners 152, edge termination structure 154, source pads 156, additional bond pads 158, and/or the drain attach pad 148 may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, at least a portion of one or more of the gate pad 150, gate runners 152, edge termination structure 154, source pads 156, additional bond pads 158, and/or the drain attach pad 148 may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

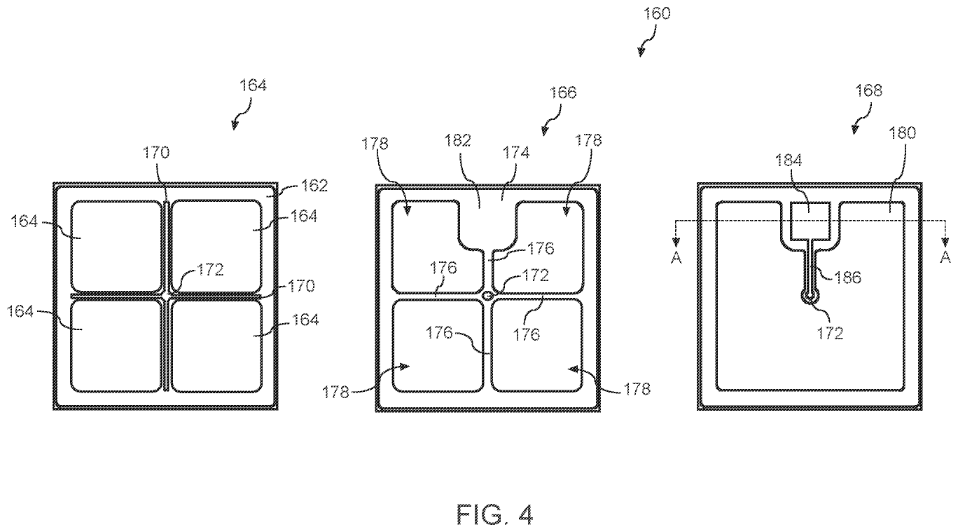

FIG. 4 depicts example metallization layers of a semiconductor device 160 that includes multiple topside metallization layers on a semiconductor structure 162, including a first metallization layer 164 and a second metallization layer 166 overlapping at least a portion of the first metallization layer 164. An insulating layer 168 may be between the first metallization layer 164 and the second metallization layer 166.

The first metallization layer 164 may be on the semiconductor structure 162. The semiconductor structure 162 may include one or more wide band gap semiconductor materials and may include doping and/or different epitaxial layer structures to form one or more active semiconductor cells for semiconductor devices (e.g., silicon carbide-based MOSFETs, silicon carbide-based Schottky diodes, Group III-nitride based HEMTs, etc.). The semiconductor structure 162 may include one or more epitaxial layers formed on a substrate, such as a silicon carbide substrate.

The first metallization layer 164 may include metallization structures, including gate runners 170 and a gate via 172. The plurality of gate runners 170 (e.g., gate buses) are used to distribute a gate signal through the semiconductor device 160. The plurality of gate runners 170 of FIG. 4 form a gate runner network. The gate runner network of FIG. 4 is a crosshairs gate runner network. More particularly, two gate runners may intersect one another in a central portion of the first metallization layer 164 and may be about perpendicular to one another. In addition, the two gate runners may have about the same length or may have differing lengths. Other suitable gate runner configurations/networks may be used without deviating from the scope of the present disclosure.

The gate via 172 may be used to communicate signals to the gate runners 170. The gate via 172 may extend through a central portion of the semiconductor device 150. However, other suitable configurations and/or locations of gate vias may be used without deviating from the scope of the present disclosure.

An insulating layer 168 may be on the first metallization layer 164. The insulating layer 168 may include an insulating portion 174. The insulating portion 174 may be a dielectric material (e.g., silicon nitride, polymer, etc.). The insulating portion 174 may be patterned to insulate or to mask the one or more metallization structures of the first metallization layer 164. More particularly, the insulating portion 174 may be patterned to cover certain structures in the first metallization layer 164 while leaving other features (e.g., portions of active regions of the semiconductor structure 144) uncovered.

For instance, the insulating portion 174 may include masking portions 176 operable to insulate or to mask the gate runners 170 of the first metallization layer 164. The insulating portion 174 may be patterned to form source contact openings 178. The source contact openings 178 may accommodate source contacts extending from, for instance, a source bond pad 180 on the second metallization layer 166. The insulating portion 174 may include a gate pad portion 182. The gate via 172 may extend through the insulating portion 174 of the insulating layer 168.

The second metallization layer 166 may be on the insulating layer 168 such that the insulating layer 168 is between the first metallization layer 164 and the second metallization layer 166. In some embodiments, the second metallization layer 166 may act as a bonding layer for the semiconductor device 160. In the example of FIG. 4, the second metallization layer 166 includes a gate pad 184 at a center edge region of the semiconductor device 160, which may be a useful location for packaging. The second metallization layer 166 may include a planar interconnect structure 186 that conductively electrically connects the gate pad 184 with the gate via 172 and thus to the gate runners 170 of the semiconductor device 160. The second metallization layer 166 may include a large source bonding pad 180. Source contact(s) may extend from the source pad 180 through the source contact openings 178 of the insulating layer 168 to the active regions of the semiconductor structure 162 of the semiconductor device 160.

The second metallization layer 166 may be used for interconnection of the semiconductor device 160 to elements of a semiconductor package, including submounts, lead frames, terminals, etc. Interconnection methods may vary based on package type, but may include wire bonding, soldering, sintering, conductive epoxy, or similar electrically conductive material.

The semiconductor device 160 may include other structures without deviating from the scope of the present disclosure. For instance, the semiconductor device 160 may include a backside metallization layer (not shown) including a drain attach pad on the backside of the semiconductor structure 160. The semiconductor device 160 may include a passivation layer (not shown) on the second metallization layer 166. The semiconductor device 160 may include an edge termination structure.

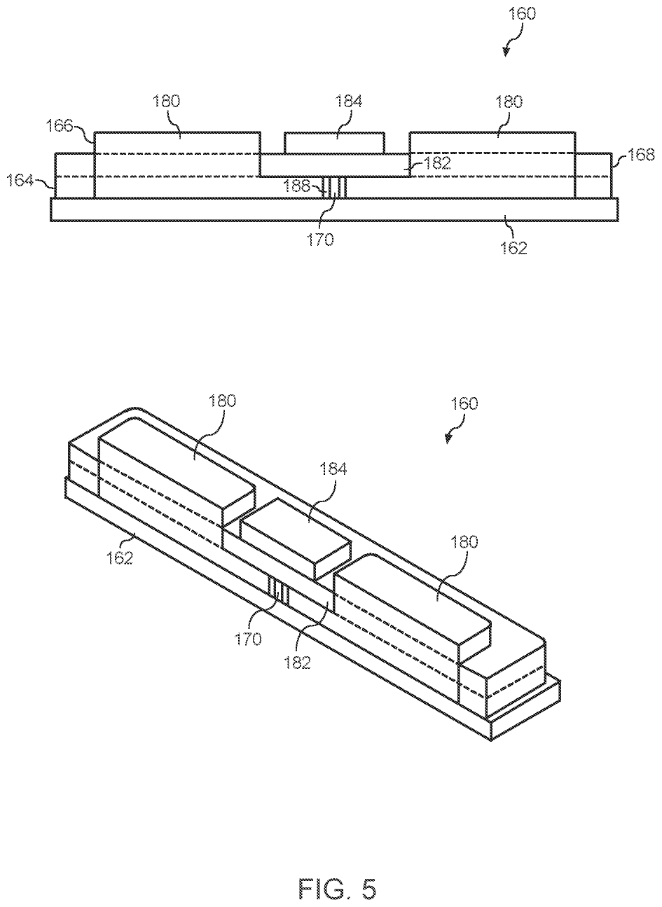

FIG. 5 depicts a cross-sectional view of the semiconductor device 160 of FIG. 4 taken along line A-A′. FIG. 5 is intended to represent structures for identification and description and is not intended to represent the structures to physical scale. As shown, the power semiconductor device 160 includes a first metallization layer 164 on a semiconductor structure 162. The semiconductor device 160 includes an insulating layer 168. The semiconductor device 160 includes a second metallization layer 166 (e.g., a bonding layer). Certain layer boundaries are illustrated in dashed line for purposes of illustration. Those of ordinary skill in the art, using the disclosures provided herein, will understand that the layers of the power semiconductor device 160 may all be assembled together to form a composite structure that may or may not include discrete layer boundaries in the final assembled semiconductor device 160.

As shown in FIG. 5, the power semiconductor device 160 includes the gate pad 184 and the source pad 180 in the second metallization layer 166. The insulating portion of the insulating layer 168 includes a gate pad portion 182. The first metallization layer 164 includes the gate runner 170. An insulating portion 188 may separate the gate runner 170 from other metallization structures (e.g., source contact). The insulating layer 168 includes source contact openings to accommodate the source contact extending from the source pad 180 to the active region of the semiconductor structure 142.

According to example embodiments of the present disclosure, at least a portion of one or more of the metallization structures of FIGS. 4 and 5, including at least a portion of one or more of the first metallization layer 164 and/or the second metallization layer 166, may include beryllium. For instance, in some embodiments, at least a portion of one or more of the first metallization layer 164 and/or the second metallization layer 166 may include a beryllium alloy. At least a portion of one or more of the first metallization layer 164 and/or the second metallization layer 166 may include copper and beryllium (e.g., a copper-beryllium alloy). At least a portion of one or more of the first metallization layer 164 and/or the second metallization layer 166 may include aluminum and beryllium (e.g., an aluminum-beryllium alloy).

In some examples, at least a portion of one or more of the first metallization layer 164 and/or the second metallization layer 166 may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, at least a portion of one or more of the first metallization layer 164 and/or the second metallization layer 166 may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

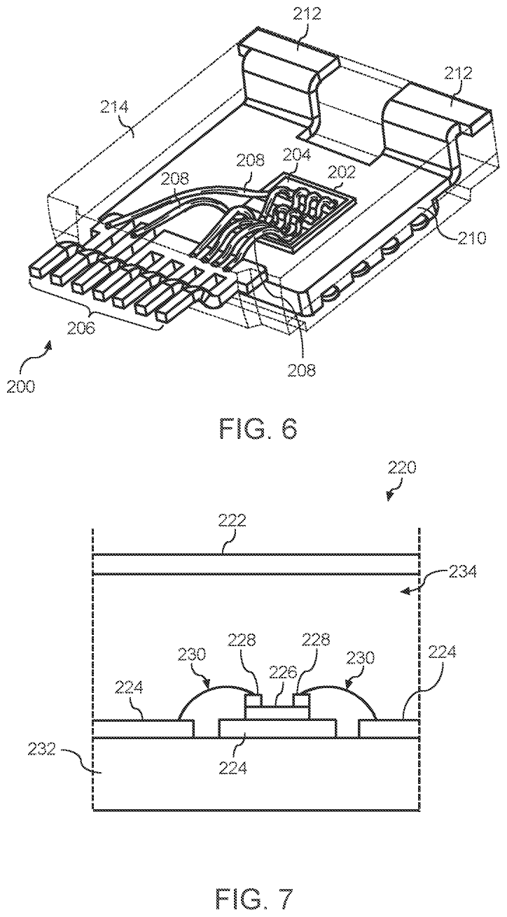

FIG. 6 depicts an example semiconductor package of a semiconductor device 200 according to example embodiments of the present disclosure. The semiconductor device includes a semiconductor die 202. The semiconductor die 202 includes one or more metallization structures, including bonding pads 204. The bonding pads 204 may be coupled to one or more electrical leads 206 using wire bonds 208. The wire bonds 208 may be aluminum and/or copper. The wire bonds 208 may have a thickness of about 15 mil to about 20 mil (e.g., about 381 μm to about 508 μm). The bonding pads 204 may have a thickness, for instance, of about 4 μm or less. A backside metallization layer on the semiconductor die 202 may be coupled to a submount 210 (e.g., a lead frame) using, for instance, a die-attach material. The submount 210 may be coupled to one or more termination structures 212. An encapsulating material 214 (e.g., EMC) may encapsulate the semiconductor die 202 including its metallization structures, wire bonds 208, submount 210, and other portions of the semiconductor package.

According to example embodiments of the present disclosure, at least a portion of one or more of the metallization structures of the semiconductor die 202, including at least a portion of one or more of the bonding pads 204 and/or the backside metallization layer, may include beryllium. For instance, in some embodiments, the metallization structures of the semiconductor die 202 may include a beryllium alloy. The metallization structures of the semiconductor die 202 may include copper and beryllium (e.g., a copper-beryllium alloy). The metallization structures of the semiconductor die 202 may include aluminum and beryllium (e.g., an aluminum-beryllium alloy).

In some examples, the metallization structures of the semiconductor die 202 may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, the metallization structures of the semiconductor die 202 may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

FIG. 7 depicts a cross-sectional view of an example semiconductor package of a semiconductor device 220 according to example embodiments of the present disclosure. FIG. 7 is intended to represent structures for identification and description and is not intended to represent the structures to physical scale. The semiconductor device 220 may include a housing 222. The semiconductor device 220 may include a conductive submount 224 (e.g., a patterned conductive submount) on which a semiconductor die 226 is mounted (e.g., using a die-attach material. The semiconductor die 226 may include one or more metallization structures, such as bonding pads 228. In some embodiments, the semiconductor die 226 may be connected to the conductive submount 224 using wire bonds 230. The conductive submount 224 may be mounted on a base layer 232 (e.g., an insulating layer). An inert gel 234 may fill the space between the semiconductor die 226 and the housing 222.

According to example embodiments of the present disclosure, at least a portion of one or more of the metallization structures of the semiconductor die 226, including at least a portion of one or more of the bonding pads 228 may include beryllium. For instance, in some embodiments, the metallization structures of the semiconductor die 226 may include a beryllium alloy. The metallization structures of the semiconductor die 226 may include copper and beryllium (e.g., a copper-beryllium alloy). The metallization structures of the semiconductor die 226 may include aluminum and beryllium (e.g., an aluminum-beryllium alloy).

In some examples, the metallization structures of the semiconductor die 226 may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, the metallization structures of the semiconductor die 226 may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

FIGS. 6 and 7 depict example semiconductor packages for purposes of illustration and discussion. Those of ordinary skill in the art, using the disclosures provided herein, will understand that different semiconductor package configurations may be used without deviating from the scope of the present disclosure.

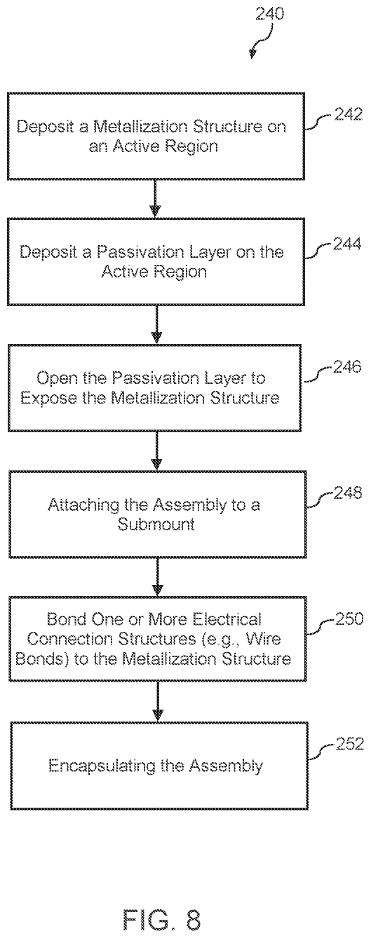

FIG. 8 depicts a flow chart of an example method 240 according to example embodiments of the present disclosure. FIG. 8 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 242, the method includes depositing a metallization structure on an active region of a semiconductor structure. The semiconductor structure may be a semiconductor structure may include one or more wide band gap semiconductor materials and may include doping and/or different epitaxial layer structures to form one or more active semiconductor cells (e.g., wide band gap semiconductor cells) for semiconductor devices (e.g., silicon carbide-based MOSFETs, silicon carbide-based Schottky diodes, Group III-nitride based HEMTs, etc.). The metallization structure may be any of the metallization structures described in the present disclosure. As one example, the method may include depositing the metallization structures 104 on the active region of the semiconductor structure 102 of FIG. 1.

According to example embodiments of the present disclosure, at least a portion of the metallization structure may include beryllium. For instance, at least a portion of the metallization structure may include a beryllium alloy. The metallization structure may include copper and beryllium (e.g., a copper-beryllium alloy). The metallization structure may include aluminum and beryllium (e.g., an aluminum-beryllium alloy).

In some examples, the metallization structure may include a ternary beryllium alloy. The ternary beryllium alloy may include aluminum (or copper), beryllium, and a ternary element. The ternary element may include silver, copper, magnesium, silicon, titanium, vanadium, or zinc. In some embodiments, the ternary element may include cobalt, which can increase microstructural stability of the metallization structure.

In example aspects of the present disclosure, the metallization structure may include about 0.1% beryllium to about 3% beryllium, such as about 0.2% beryllium to about 2% beryllium, such as about 0.2% beryllium to about 0.1% beryllium, such as about 0.2% beryllium to about 0.5% beryllium, such as about 0.5% beryllium.

At 244 of FIG. 8, the method may include depositing a passivation layer on the active region of the semiconductor structure. In some examples, the passivation layer may include silicon nitride. The passivation layer may include a polymer, such as polyimide. In some examples, the passivation layer may be SiO₂, MgOx, MgNx, ZnO, SiNx, SiOx or other dielectric material. As an example, the passivation layer 110 may be deposited on the semiconductor structure 102 of FIG. 1.

At 246 of FIG. 8, the method may include opening the passivation layer to expose the metallization structure. For instance, the method may include opening the passivation layer 110 to expose the bonding pads 104 of FIG. 1.

At 248 of FIG. 8, the method may include attaching an assembly including the semiconductor structure, the metallization structure, and/or the passivation layer to a submount such as a lead frame. For instance, the method may include attaching the backside metallization structure 108 of FIG. 1 to a submount (e.g., using a die-attach material).

At 250 of FIG. 8, the method may include bonding one or more electrical connection structures (e.g., wire bonds) to the metallization structures. For instance, wire bonds may be bonded to the metallization structures 104 of FIG. 1.

At 252 of FIG. 8, the method may include encapsulating the assembly including the semiconductor structure, the metallization structure, and/or the passivation layer. For instance, the assembly may be encapsulated with an EMC.

Examples of the present disclosure are provided below. Features of some examples may be combined with features of other examples without deviating from the scope of the present disclosure.

One example aspect of the present disclosure is directed to a semiconductor device. The semiconductor device includes an active region comprising one or more active semiconductor cells. The semiconductor device includes a metallization structure on the active region. The metallization structure comprises beryllium.

In some examples, the metallization structure is one or more of a contact, interconnect, or bonding pad for the semiconductor device.

In some examples, the metallization structure further comprises copper. In some examples, the metallization structure comprises aluminum.

In some examples, the metallization structure comprises a range of about 0.1% beryllium to about 3% beryllium. In some examples, the metallization structure comprises a range of about 0.1% beryllium to about 3% beryllium. In some examples, the metallization structure comprises a range of about 0.2% beryllium to about 0.5% beryllium.

In some examples, the metallization structure comprises a ternary beryllium alloy. In some examples, the ternary beryllium alloy comprises aluminum, beryllium, and a ternary element, wherein the ternary element comprises silver, copper, magnesium, silicon, titanium, vanadium, or zinc. In some examples, the ternary beryllium alloy comprises aluminum, beryllium, and a ternary element, wherein the ternary element comprises cobalt.

In some examples, the metallization structure comprises a source contact, a drain contact, or a gate contact for a MOSFET.

In some examples, the semiconductor device further comprises a passivation layer. In some examples, the passivation layer comprises silicon nitride. In some examples, the passivation layer comprises a polymer. In some examples, the polymer comprises polyimide.

In some examples, the one or more active semiconductor cells comprise a wide band gap semiconductor. In some examples, the one or more active semiconductor cells comprise one or more silicon carbide-based MOSFETs. In some examples, the one or more active semiconductor cells comprise one or more silicon carbide-based Schottky diodes. In some examples, the one or more active semiconductor cells comprise one or more Group III-nitride based high electron mobility transistor devices.

Another example aspect of the present disclosure is directed to a semiconductor device. The semiconductor device includes an active region comprising one or more silicon carbide-based MOSFETs. The semiconductor device includes a metallization structure on the active region. The metallization structure includes a bonding pad associated with a gate contact, a source contact, or a drain contact for the semiconductor device. The metallization structure comprises beryllium.

In some examples, the metallization structure further comprises copper. In some examples, the metallization structure further comprises aluminum.

In some examples, the metallization structure comprises a range of about 0.1% beryllium to about 3% beryllium. In some examples, the metallization structure comprises a range of about 0.1% beryllium to about 3% beryllium. In some examples, the metallization structure comprises a range of about 0.2% beryllium to about 0.5% beryllium.

In some examples, the metallization structure comprises a ternary beryllium alloy. In some examples, the ternary beryllium alloy comprises aluminum, beryllium, and a ternary element, wherein the ternary element comprises silver, copper, magnesium, silicon, titanium, vanadium, or zinc. In some examples, the ternary beryllium alloy comprises aluminum, beryllium, and a ternary element, wherein the ternary element comprises cobalt.

In some examples, the semiconductor device includes an adhesion layer between the metallization structure and the active region. In some examples, the adhesion layer comprises titanium.

In some examples, the semiconductor device comprises a passivation layer. In some examples, the passivation layer comprises silicon nitride. In some examples, the passivation layer comprises a polymer. In some examples, the polymer comprises polyimide.

In some examples, the semiconductor device includes an encapsulating material.

In some examples, the semiconductor device includes one or more wire bonds on the metallization structure.

Another example aspect of the present disclosure is directed to a method. The method includes depositing a metallization structure on an active region comprising one or more wide band gap semiconductor cells. The metallization structure comprises beryllium.

In some examples, the metallization structure is one or more of a contact, interconnect, or bonding pad for the semiconductor device.

In some examples, the metallization structure further comprises copper. In some examples, the metallization structure comprises aluminum.

In some examples, the metallization structure comprises a range of about 0.1% beryllium to about 3% beryllium. In some examples, the metallization structure comprises a range of about 0.1% beryllium to about 3% beryllium. In some examples, the metallization structure comprises a range of about 0.2% beryllium to about 0.5% beryllium.

In some examples, the metallization structure comprises a ternary beryllium alloy. In some examples, the ternary beryllium alloy comprises aluminum, beryllium, and a ternary element, wherein the ternary element comprises silver, copper, magnesium, silicon, titanium, vanadium, or zinc. In some examples, the ternary beryllium alloy comprises aluminum, beryllium, and a ternary element, wherein the ternary element comprises cobalt.

In some examples, the method may include depositing a passivation layer on the active region. In some examples, the method may include opening the passivation layer to expose the metallization structure; and bonding one or more electrical connection structures to the metallization structure.

In some examples, the method may include attaching an assembly comprising the active region and the metallization structure to a lead frame; and encapsulating the assembly.

In some examples, the one or more active semiconductor cells comprise a wide band gap semiconductor. In some examples, the one or more active semiconductor cells comprise one or more silicon carbide-based MOSFETs. In some examples, the one or more active semiconductor cells comprise one or more silicon carbide-based Schottky diodes. In some examples, the one or more active semiconductor cells comprise one or more Group III-nitride based high electron mobility transistor devices.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
an active region comprising one or more active semiconductor cells;
a metallization structure on the active region; and
wherein the metallization structure comprises beryllium.

2. The semiconductor device of claim 1, wherein metallization structure is one or more of a contact, interconnect, or bonding pad for the semiconductor device.

3. The semiconductor device of claim 1, wherein the metallization structure further comprises copper.

4. The semiconductor device of claim 1, wherein the metallization structure further comprises aluminum.

5. The semiconductor device of claim 1, wherein the metallization structure comprises a range of about 0.1% beryllium to about 3% beryllium.

6. The semiconductor device of claim 1, where the metallization structure comprises a range of about 0.2% beryllium to about 0.5% beryllium.

7. The semiconductor device of claim 1, wherein the metallization structure comprises a ternary beryllium alloy.

8. The semiconductor device of claim 7, wherein the ternary beryllium alloy comprises aluminum, beryllium, and a ternary element, wherein the ternary element comprises silver, copper, magnesium, silicon, titanium, vanadium, or zinc.

9. The semiconductor device of claim 7, wherein the ternary beryllium alloy comprises aluminum, beryllium, and a ternary element, wherein the ternary element comprises cobalt.

10. The semiconductor device of claim 1, wherein the metallization structure comprises a source contact, a drain contact, or a gate contact for a MOSFET.

11. The semiconductor device of claim 1, wherein the semiconductor device further comprises a passivation layer.

12. The semiconductor device of claim 11, wherein the passivation layer comprises silicon nitride.

13. The semiconductor device of claim 11, wherein the passivation layer comprises a polymer.

14. The semiconductor device of claim 13, wherein the polymer comprises polyimide.

15. The semiconductor device of claim 1, wherein the one or more active semiconductor cells comprise a wide band gap semiconductor.

16. The semiconductor device of claim 1, wherein the one or more active semiconductor cells comprise one or more silicon carbide-based MOSFETs.

17. The semiconductor device of claim 1, wherein the one or more active semiconductor cells comprise one or more silicon carbide-based Schottky diodes.

18. The semiconductor device of claim 1, wherein the one or more active semiconductor cells comprise one or more Group III-nitride based high electron mobility transistor devices.

19. A semiconductor device, comprising:
an active region comprising one or more silicon carbide-based MOSFETs;
a metallization structure on the active region, the metallization structure comprising a bonding pad associated with a gate contact, a source contact, or a drain contact for the semiconductor device; and
wherein the metallization structure comprises beryllium.

20.-34. (canceled)

35. A method, comprising:
depositing a metallization structure on an active region comprising one or more wide band gap semiconductor cells; and
wherein the metallization structure comprises beryllium.

36.-49. (canceled)
